(19) United States
(12) Patent Application Publication
(10) Pub. No.: US 2008/0224223 A1
(43) Pub. Date: Sep. 18, 2008

(54) SEMICONDUCTOR DEVICE AND METHOD FOR FABRICATING THE SAME

(75) Inventor: Junji HIRASE, Osaka (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 12/017,839

(22) Filed: Jan. 22, 2008

(30) Foreign Application Priority Data
Mar. 15, 2007 (JP) 2007-066653

(51) Int. Cl. H01L 29/00; H01L 21/3205

(52) U.S. Cl. 257/365; 438/587; 257/E29.001; 257/E21.294

(57) ABSTRACT

A semiconductor device includes: a first gate electrode formed above a first active region in a substrate with a first gate insulating film interposed therebetween; and a second gate electrode formed above a second active region in the substrate with a second gate insulating film interposed therebetween. The first gate electrode has a shorter gate length than the second gate electrode, the first gate electrode is fully silicided, and at least a portion of the second gate electrode in contact with the second gate insulating film is not silicided.

### BACKGROUND OF THE INVENTION

(a) Fields of the Invention

The present invention relates to structures of semiconductor devices and their fabrication methods. In particular, the present invention relates to semiconductor devices with FUSI (Fully Silicided) gate type MISFETs (Metal Insulator Semiconductor Field Effect Transistors) incorporated therein, and to their fabrication methods.

(b) Description of Related Art

With recent enhancement of integration density, functionality, and speed of a semiconductor integrated circuit device, MISFETs therein have been increasingly miniaturized at a rapid pace. However, such miniaturization reveals various problems that will degrade the driving capability of the MISFET. For example, a conventional MISFET employs as a gate electrode a polysilicon electrode doped with impurities. Thus, during operation of the MISFET, a portion of the gate electrode located around the interface with a gate insulating film thereof becomes depleted to generate the gate depletion layer capacitance. This gate depletion layer acts as an added layer in series with the gate insulating film, so that during the MISFET operation, the effective thickness of the gate insulating film increases to hinder full use of the driving capability. Since the influence of this gate depletion to the driving power increases as the MISFET becomes finer and the gate insulating film becomes thinner, the gate depletion will cause a serious problem involving the limitation of miniaturization.

To overcome this gate depletion problem, a proposal is made of the structure in which a gate electrode is metallized to prevent depletion thereof. An example of such structure is a FUSI (fully silicided) gate structure.

The FUSI gate structure is produced as follows. First, a polysilicon film typically used as the material for a gate electrode is deposited, and the polysilicon film is patterned into a gate electrode shape. Subsequently, source-drain regions are formed. Then, a metal film for silicidation such as Ni is deposited, and a thermal treatment is performed to fully silicide the polysilicon electrode. FIGS. 8A and 8B show exemplary plan and cross-sectional structures of a conventional semiconductor device having the thus formed FUSI gate structure, respectively. FIG. 8B is a sectional view taken along the line VIII-VIII in FIG. 8A.

Referring to FIGS. 8A and 8B, a surface portion of a semiconductor substrate 1 is formed with an STI (shallow trench isolation) 2 to define a Short-Lg MISFET active region 3A and a Long-Lg MISFET active region 3B. Over the Short-Lg MISFET active region 3A, a first FUSI gate electrode 5A with a first gate length is formed to extend across the active region 3A with a first gate insulating film 4A interposed therebetween. Over the Long-Lg MISFET active region 3B, a second FUSI gate electrode 5B with a second gate length greater than the first gate length is formed to extend across the active region 3B with a second gate insulating film 4B interposed therebetween. First extension regions 6A are formed in portions of the Short-Lg MISFET active region 3A located outside the first FUSI gate electrode 5A, respectively. Second extension regions 6B are formed in portions of the Long-Lg MISFET active region 3B located outside the second FUSI gate electrode 5B, respectively. First insulating sidewall spacers 7A and second insulating sidewall spacers 7B are formed on side surfaces of the first FUSI gate electrode 5A and the second FUSI gate electrode 5B, respectively. First source-drain regions 8A are formed in portions of the Short-Lg MISFET active region 3A located below the outer sides of the first insulating sidewall spacers 7A when viewed from the first FUSI gate electrode 5A, respectively. Second source-drain regions 8B are formed in portions of the Long-Lg MISFET active region 3B located below the outer sides of the second insulating sidewall spacers 7B when viewed from the second FUSI gate electrode 5B, respectively. An interlayer insulating film 9 is formed over the semiconductor substrate 1 including the tops of the first and second FUSI gate electrodes 5A and 5B.

Non-patent Document 1: J. A. Kittl et al. “Scalability of Ni FUSI gate process: phase and Vt control to 30 nm gate lengths” 2005 Symposium on VLSI Technology Digest of Technical Papers, pp. 72-73

### SUMMARY OF THE INVENTION

With the full silicidation technique as described above, however, as reported in Non-patent Document 1, when the polysilicon electrode is fully silicided, deposited metal enters into the polysilicon electrode from not only the top but also the side of the electrode and contributes to silicidation reaction. This makes it difficult to form the gate electrode with a short gate length and the gate electrode with a long gate length both of which have silicide compositions with the same stoichiometry. That is to say, the composition and the like of the FUSI gate electrode greatly depend on the gate length, which leads to an extremely small margin for full silicide formation. For example, in the case where the condition for full silicide formation is set to be optimum for the gate electrode with a short gate length, the gate electrode with a long gate length is not fully silicided and a polysilicon portion remains in the lower portion thereof. This will cause variations in threshold voltage Vt.

To deal with such a problem, multi-step silicidation as described below is attempted. For example, first, a metal film for silicidation is deposited on a polysilicon electrode, and then a first low-temperature thermal treatment for full silicidation (at about 300° C. or lower) is performed. Thereafter, unreacted metal is selectively removed and then a second high-temperature thermal treatment for full silicidation (at about 500° C. or lower) is performed. In this case, however, the silicidation process becomes complicated.

Moreover, as miniaturization of the device further advances, the types of gate lengths still further increase. Therefore, it is expected that the margin for full silicidation will be increasingly narrower in the future.

In view of the foregoing, an object of the present invention is to offer a simple full-silicidation technique capable of stably providing a high-performance device incorporating MISFETs with high driving capability even in the case of further miniaturization of the device and further increase in the types of gate lengths.

To attain the above object, the inventors made various evaluations. Then, the inventors achieved the invention that in a semiconductor device having a plurality of gate electrodes with different gate lengths, full silicidation is performed only on a gate electrode with a specific gate length, for example, only on a gate electrode with a short gate length in a MISFET required for speed enhancement.

To be more specific, a semiconductor device according to the present invention includes: a first gate electrode formed above a first active region in a substrate with a first gate insulating film interposed therebetween; and a second gate electrode formed above a second active region in the substrate with a second gate insulating film interposed therebetween. In this device, the first gate electrode has a shorter gate length than the second gate electrode, the first gate electrode is fully silicided, and at least a portion of the second gate electrode in contact with the second gate insulating film is not silicided.

With the semiconductor device of the present invention, full silicidation is not performed on the gate electrode with a long gate length which makes no contribution to speed enhancement of the device, while full silicidation is selectively performed on the gate electrode with a short gate length which makes significant contribution to speed enhancement of the device. Thus, even though miniaturization of the device further advances to narrow the margin for full silicidation, a high-performance device incorporating MISFETs with high driving capability can be provided reliably.

In the semiconductor device according to the present invention, the gate length (the short gate length) of the first gate electrode may range from the minimum design rule to twice the minimum design rule, inclusive. Note that the minimum design rule covered by the present invention is, for example, about 10 to 60 nm.

In the semiconductor device according to the present invention, the second gate electrode (the gate electrode with a long gate length) may have a silicide layer formed at least in its upper portion. In this case, the second gate electrode may have a silicidation blocking layer formed below the silicide layer. The silicidation blocking layer may be made of metal having a higher melting point than the silicidation temperature of the silicide layer, TiN, metal oxide, or silicon having nitrogen or oxygen added thereto. Preferably, the silicidation blocking layer is basically made of a conductive material. However, as the silicidation blocking layer, use may be made of an insulating film such as a native oxide film having such an extremely small thickness as not to affect the conductivity of the whole of the gate electrode.

In the semiconductor device according to the present invention, the first gate insulating film (the gate insulating film below the gate electrode with a short gate length) may be made of a high dielectric constant material. In the present application, the high dielectric constant material is a material such as Hf- or Al-based oxide with a relative dielectric constant of 10 or higher.

In the semiconductor device according to the present invention, at least a portion of the second gate electrode in contact with the second gate insulating film may be made of silicon.

A method for fabricating a semiconductor device according to the present invention includes: the step (a) of forming a silicon-containing film over a substrate having a first active region and a second active region; the step (b) of patterning the silicon-containing film to form a first gate electrode above the first active region and a second gate electrode above the second active region, the first gate electrode having a first gate length, the second gate electrode having a longer second gate length than the first gate length; and the step (c) of fully siliciding the first gate electrode. In this method, in the step (c), at least a portion of the second gate electrode in contact with the second gate insulating film is not silicided.

With the method for fabricating a semiconductor device according to the present invention, the above-described semiconductor device according to the present invention can be fabricated. That is to say, full silicidation is not performed on the gate electrode with a long gate length which makes no contribution to speed enhancement of the device, while full silicidation is selectively performed on the gate electrode with a short gate length which makes significant contribution to speed enhancement of the device. Thus, even though miniaturization of the device further advances to narrow the margin for full silicidation, a high-performance device incorporating MISFETs with high driving capability can be provided stably in a simple manner.

In the method for fabricating a semiconductor device according to the present invention, in the step (c), the first gate electrode may be fully silicided with the second gate electrode covered with an anti-silicidation film. With this method, only by adding, to the conventional full silicidation process, the step of covering the second gate electrode (the gate electrode with a long gate length) with the anti-silicidation film, the above-described semiconductor device according to the present invention can be fabricated.

The method for fabricating a semiconductor device according to the present invention may further include, between the steps (b) and (c), the step of siliciding an upper portion of the second gate electrode.

In the method for fabricating a semiconductor device according to the present invention, in the step (a), a silicidation blocking layer may be formed inside a portion of the silicon-containing film located over the second active region, and in the step (c), the first gate electrode may be fully silicided and simultaneously a portion of the second gate electrode located on the top of the silicidation blocking layer may be silicided. With this method, only by adding, to the conventional full silicidation process, the step of forming the silicidation blocking layer in a portion of the silicon-containing film to be the gate electrode with a long gate length, the above-described semiconductor device according to the present invention can be fabricated.

In the method for fabricating a semiconductor device according to the present invention, in the step (a), after formation of the silicon-containing film, impurities may be selectively implanted into a portion of the silicon-containing film located over the second active region, thereby forming the silicidation blocking layer. Alternatively, in the step (a), a first silicon-containing film as a lower-layer portion of the silicon-containing film may be formed over the substrate, the silicidation blocking layer may then be formed on a portion of the first silicon-containing film located over the second active region, and thereafter a second silicon-containing film as an upper-layer portion of the silicon-containing film may be formed on the first silicon-containing film including the top of the silicidation blocking layer.

The method for fabricating a semiconductor device according to the present invention may further include, before the step (a), the step of forming a gate insulating film made of a high dielectric constant material at least on the first active region.

As described above, with the present invention, in a semiconductor device having a plurality of gate electrodes with different gate lengths, full silicidation is selectively performed on a gate electrode with a short gate length in a MISFET required for speed enhancement. Therefore, even in the case of further miniaturization of the device and further increase in the types of gate lengths, a high-performance device incorporating MISFETs with high driving capability can be provided stably in a simple manner.

That is to say, when the present invention is employed for various types of electronic devices incorporating FUSI gate type MISFETs, a high-performance device incorporating MISFETs with high driving capability can be provided stably in a simple manner. Therefore, the present invention is of very usefulness.

### BRIEF DESCRIPTION OF THE DRAWINGS

FIG. 1A is a plan view of a semiconductor device according to a first embodiment of the present invention, and FIG. 1B is a sectional view thereof taken along the line I-I in FIG. 1A.

FIG. 2A is a plan view of a semiconductor device according to a second embodiment of the present invention, and FIG. 2B is a sectional view thereof taken along the line II-II in FIG. 2A.

FIGS. 3A to 3F are sectional views showing process steps of a method for fabricating a semiconductor device according to a third embodiment of the present invention.

FIGS. 4A to 4D are sectional views showing process steps of the method for fabricating a semiconductor device according to the third embodiment of the present invention.

FIGS. 5A to 5E are sectional views showing process steps of a method for fabricating a semiconductor device according to a fourth embodiment of the present invention.

FIGS. 6A to 6D are sectional views showing process steps of the method for fabricating a semiconductor device according to the fourth embodiment of the present invention.

FIGS. 7A to 7E are sectional views showing process steps of a method for fabricating a semiconductor device according to one modification of the fourth embodiment of the present invention.

FIG. 8A is a plan view of a conventional semiconductor device, and FIG. 8B is a sectional view thereof taken along the line VIII-VIII in FIG. 8A.

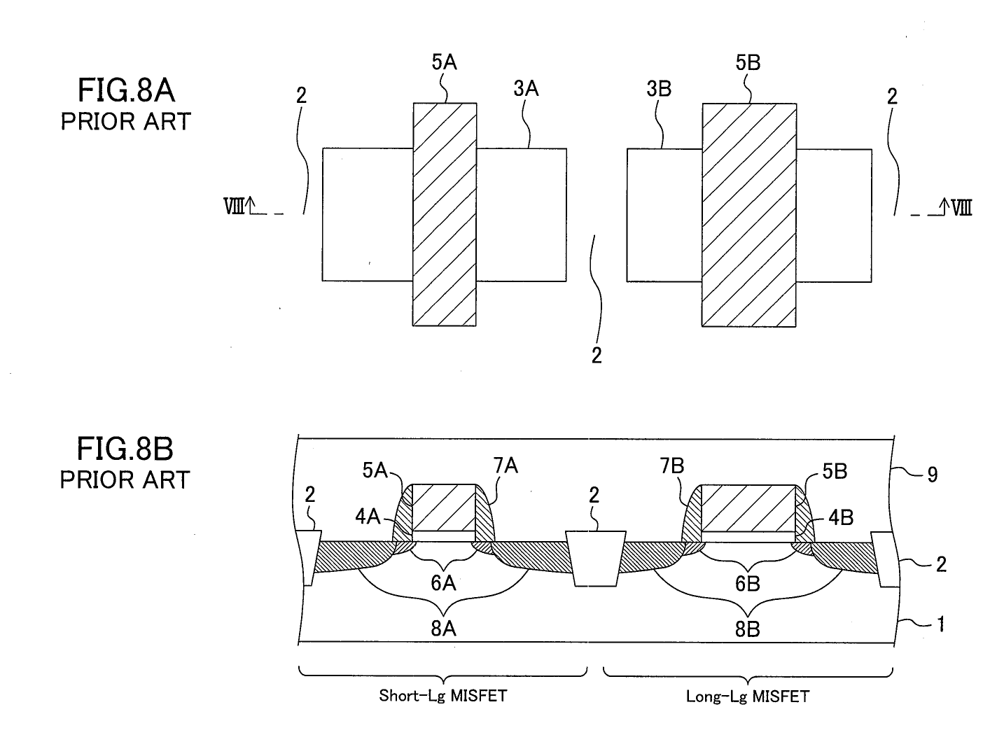

### DETAILED DESCRIPTION OF THE PREFERRED EMBODIMENTS

### First Embodiment

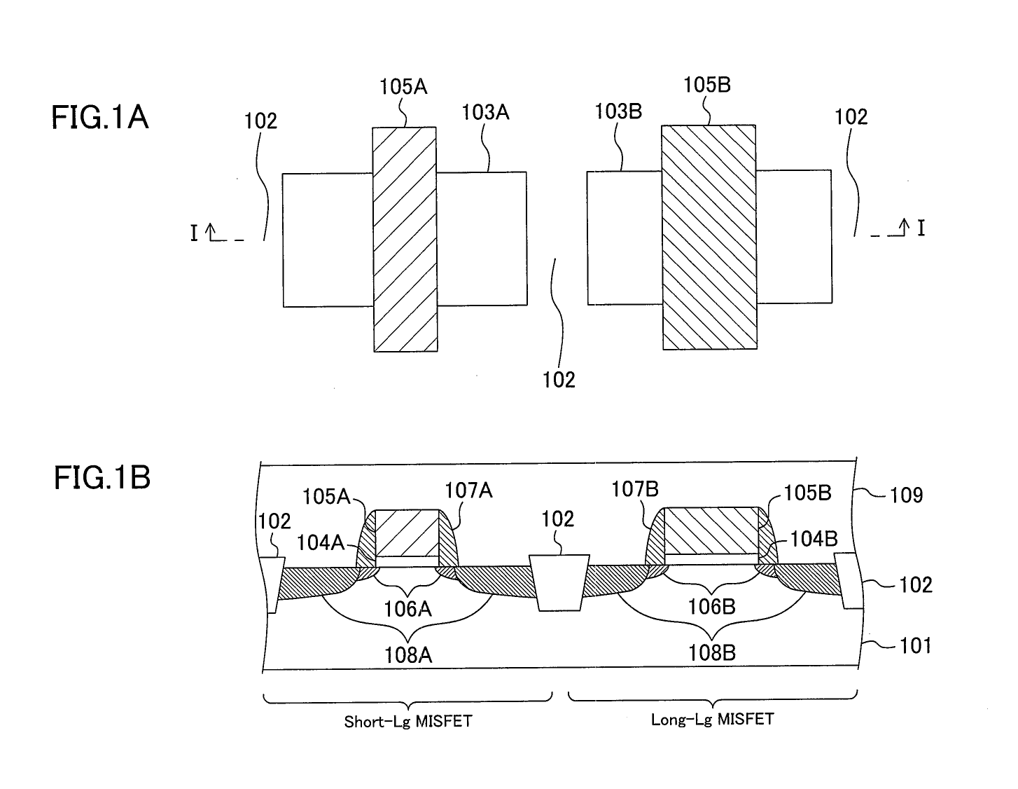

A semiconductor device according to a first embodiment of the present invention will be described below with reference to the accompanying drawings. FIG. 1A is a plan view of the semiconductor device according to the first embodiment, and FIG. 1B is a sectional view thereof taken along the line I-I in FIG. 1A. In FIG. 1A, illustration of an insulating sidewall spacer and an interlayer insulating film is omitted.

Referring to FIGS. 1A and 1B, a surface portion of a semiconductor substrate 101 formed with a well (not shown) is provided with an isolation region 102 made of, for example, an STI, thereby defining a Short-Lg MISFET active region 103A and a Long-Lg MISFET active region 103B. Over the Short-Lg MISFET active region 103A, a first gate electrode 105A fully silicided and having a first gate length is formed to extend across the active region 103A with a first gate insulating film 104A interposed therebetween. Over the Long-Lg MISFET active region 103B, a second gate electrode 105B not fully silicided and having a second gate length greater than the first gate length is formed to extend across the active region 103B with a second gate insulating film 104B interposed therebetween. In portions of the Short-Lg MISFET active region 103A located outside the first gate electrode 105A, first extension regions 106A are formed which are made of impurity diffusion layers with an opposite conductivity type to the corresponding well, respectively. In portions of the Long-Lg MISFET active region 103B located outside the second gate electrode 105B, second extension regions 106B are formed which are made of impurity diffusion layers with an opposite conductivity type to the corresponding well, respectively. First insulating sidewall spacers 107A and second insulating sidewall spacers 107B are formed on side surfaces of the first gate electrode 105A and the second gate electrode 105B, respectively. In portions of the Short-Lg MISFET active region 103A located below the outer sides of the first insulating sidewall spacers 107A when viewed from the first gate electrode 105A, first source-drain regions 108A are formed which are made of impurity diffusion layers with an opposite conductivity type to the corresponding well, respectively. In portions of the Long-Lg MISFET active region 103B located below the outer sides of the second insulating sidewall spacers 107B when viewed from the second gate electrode 105B, second source-drain regions 108B are formed which are made of impurity diffusion layers with an opposite conductivity type to the corresponding well, respectively. An interlayer insulating film 109 is formed over the semiconductor substrate 101 including the tops of the first and second gate electrodes 105A and 105B.

The first embodiment is characterized in that the first gate electrode 105A with the first gate length (a relatively short gate length) is fully silicided while the second gate electrode 105B with the second gate length (a relatively long gate length) is not fully silicided. In other words, in the first gate electrode 105A, the whole electrode including a portion in contact with the first gate insulating film 104A is silicided, while in the second gate electrode 105B, as long as at least a portion in contact with the second gate insulating film 104B is not silicided, other portions thereof, for example, the upper portion may be silicided. It goes without saying that the second gate electrode 105B may be an electrode with no silicide layer, such as the polysilicon electrode.

With the first embodiment, even in the case where in a semiconductor device having a plurality of gate electrodes with a wide range of gate lengths, it is extremely difficult to stably silicide the gate electrodes to provide the same stoichiometry thereto, selective full silicidation of only the first gate electrode 105A with a short gate length enables extremely stable formation of the first gate electrode 105A in the form of a FUSI gate electrode.

That is to say, full silicidation is not performed on the second gate electrode 105B with a long gate length which makes less contribution to speed enhancement of the device and rather requires a more stable operation due to its use for an analog circuit and the like, while full silicidation is performed only on the first gate electrode 105A with a short gate length which makes significant contribution to speed enhancement of the device. With this, depletion of the gate electrode that would adversely affect MISFET operations can be prevented to attain high driving capability. Therefore, securing of the device stability and enhancement of the device performance can be both satisfied at high levels.

The short gate length of the first gate electrode 105A may range from the minimum design rule (for example, about 10 to 60 nm) to twice the minimum design rule, inclusive. In addition, the MISFET (the Short-Lg MISFET) having the first gate electrode 105A with such a short gate length may be used in, for example, a logic circuit or a memory circuit.

The long gate length of the second gate electrode 105B may be above twice the minimum design rule described above. In addition, the MISFET (the Long-Lg MISFET) having the second gate electrode 105B with such a long gate length may be used in, for example, an analog circuit or a resistor.

In the first embodiment, as the source/drain structure, use is made of a double-diffused source/drain structure in which the lightly-diffused source/drain region (the extension region) is arranged in the vicinity of the gate edge and the heavily-diffused source/drain region is arranged outside the lightly-diffused source/drain region. However, the source/drain structure is not limited to a specific structure. In addition, the upper portion of the source/drain structure may be silicided.

In the first embodiment, the first gate insulating film 104A may be, for example, a gate insulating film made of a high dielectric constant material such as Hf- or Al-based oxide with a relative dielectric constant of 10 or higher. In this case, a silicon oxide film serving as a buffer insulating film may be inserted between the high-dielectric-constant gate insulating film and the substrate 101. With this structure, degradation of the interface between the high-dielectric-constant gate insulating film and the substrate 101 can be prevented. In the case where the first gate insulating film 104A is a high-dielectric-constant gate insulating film, the second gate insulating film 104B may be the same high- dielectric-constant gate insulating film or a gate insulating film made of another material, for example, a SiO₂ film. That is to say, the first and second gate insulating films 104A and 104B may not be composed of the same gate insulating film. Alternatively, another structure may be employed in which a relatively thin SiO₂ film is used as the first gate insulating film 104A and a relatively thick SiO₂ film is used as the second gate insulating film 104B.

In the first embodiment, an insulative substrate (a so-called SOI (semiconductor on insulator) substrate) with a semiconductor region may be used instead of the semiconductor substrate 101.

In the first embodiment, a third gate electrode having a short gate length and not fully silicided may be additionally provided as another electrode different from the fully-silicided first gate electrode 105A with a short gate length.

### Second Embodiment

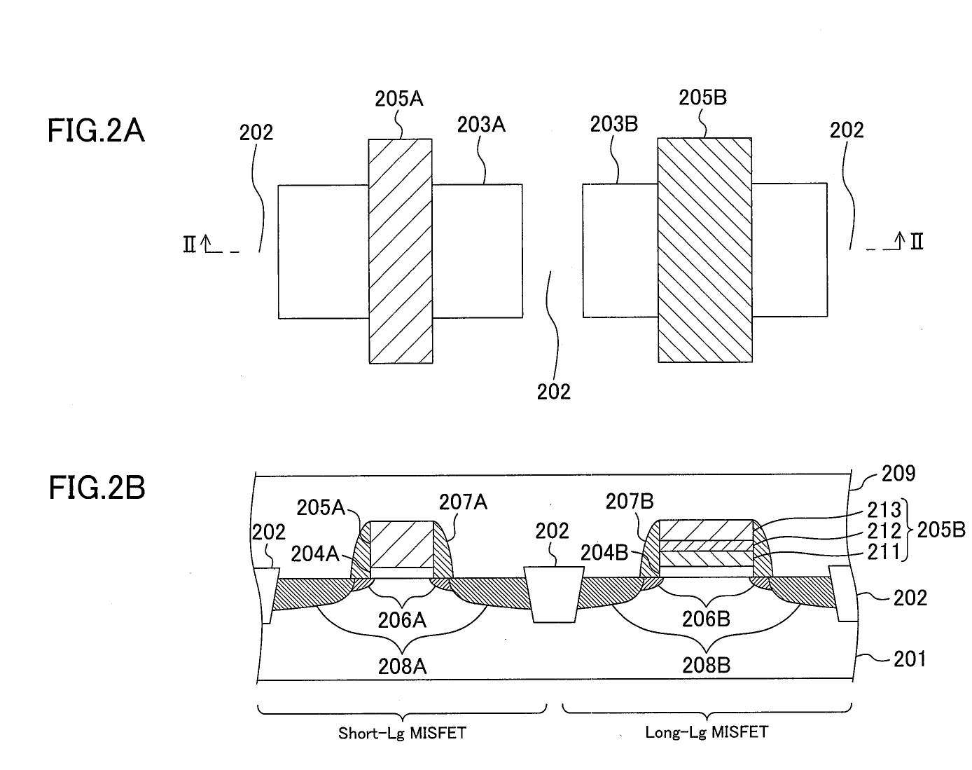

A semiconductor device according to a second embodiment of the present invention will be described below with reference to the accompanying drawings. FIG. 2A is a plan view of the semiconductor device according to the second embodiment, and FIG. 2B is a sectional view thereof taken along the line II-II in FIG. 2A. In FIG. 2A, illustration of an insulating sidewall spacer and an interlayer insulating film is omitted.

Referring to FIGS. 2A and 2B, a surface portion of a semiconductor substrate 201 formed with a well (not shown) is provided with an isolation region 202 made of, for example, an STI, thereby defining a Short-Lg MISFET active region 203A and a Long-Lg MISFET active region 203B. Over the Short-Lg MISFET active region 203A, a first gate electrode 205A fully silicided and having a first gate length is formed to extend across the active region 203A with a first gate insulating film 204A interposed therebetween. Over the Long-Lg MISFET active region 203B, a second gate electrode 205B not fully silicided and having a second gate length greater than the first gate length is formed to extend across the active region 203B with a second gate insulating film 204B interposed therebetween. In portions of the Short-Lg MISFET active region 203A located outside the first gate electrode 205A, first extension regions 206A are formed which are made of impurity diffusion layers with an opposite conductivity type to the corresponding well, respectively. In portions of the Long-Lg MISFET active region 203B located outside the second gate electrode 205B, second extension regions 206B are formed which are made of impurity diffusion layers with an opposite conductivity type to the corresponding well, respectively. First insulating sidewall spacers 207A and second insulating sidewall spacers 207B are formed on side surfaces of the first gate electrode 205A and the second gate electrode 205B, respectively. In portions of the Short-Lg MISFET active region 203A located below the outer sides of the first insulating sidewall spacers 207A when viewed from the first gate electrode 205A, first source-drain regions 208A are formed which are made of impurity diffusion layers with an opposite conductivity type to the corresponding well, respectively. In portions of the Long-Lg MISFET active region 203B located below the outer sides of the second insulating sidewall spacers 207B when viewed from the second gate electrode 205B, second source-drain regions 208B are formed which are made of impurity diffusion layers with an opposite conductivity type to the corresponding well, respectively. An interlayer insulating film 209 is formed over the semiconductor substrate 201 including the tops of the first and second gate electrodes 205A and 205B.

The second embodiment is characterized in that the first gate electrode 205A with the first gate length (a relatively short gate length) is fully silicided while the second gate electrode 205B with the second gate length (a relatively long gate length) is not fully silicided. In this embodiment, the second gate electrode 205B has the structure in which a silicon layer 211, a silicidation blocking layer 212, and a silicide layer 213 are sequentially stacked from bottom to top. In other words, in the first gate electrode 205A, the whole electrode including a portion in contact with the first gate insulating film 204A is formed into a silicide layer, while in the second gate electrode 205B, a portion in contact with the second gate insulating film 204B is formed with the silicon layer 211. Note that, for example, a silicon layer with oxygen added thereto is used as the silicidation blocking layer 212.

With the second embodiment, even in the case where in a semiconductor device having a plurality of gate electrodes with a wide range of gate lengths, it is extremely difficult to stably silicide the gate electrodes to provide the same stoichiometry thereto, selective full silicidation of only the first gate electrode 205A with a short gate length enables extremely stable formation of the first gate electrode 205A in the form of a FUSI gate electrode.

That is to say, full silicidation is not performed on the second gate electrode 205B with a long gate length which makes less contribution to speed enhancement of the device and rather requires a more stable operation due to its use for an analog circuit and the like, while full silicidation is performed only on the first gate electrode 205A with a short gate length which makes significant contribution to speed enhancement of the device. With this, depletion of the gate electrode that would adversely affect MISFET operations can be prevented to attain high driving capability. Therefore, securing of the device stability and enhancement of the device performance can be both satisfied at high levels.

Furthermore, in the second embodiment, since the silicidation blocking layer 212 is provided inside the second gate electrode 205B with a long gate length, full silicidation of the second gate electrode 205B can be prevented and simultaneously the silicide layer 213 can be formed easily in only the upper portion of the second gate electrode 205B. Therefore, the resistance of the second gate electrode 205B with a long gate length can be reduced to attain further enhancement of the device performance.

The short gate length of the first gate electrode 205A may range from the minimum design rule (for example, about 10 to 60 nm) to twice the minimum design rule, inclusive. In addition, the MISFET (the Short-Lg MISFET) having the first gate electrode 205A with such a short gate length may be used in, for example, a logic circuit or a memory circuit.

The long gate length of the second gate electrode 205B may be above twice the minimum design rule described above. In addition, the MISFET (the Long-Lg MISFET) having the second gate electrode 205B with such a long gate length may be used in, for example, an analog circuit or a resistor.

In the second embodiment, as the source/drain structure, use is made of a double-diffused source/drain structure in which the lightly-diffused source/drain region (the extension region) is arranged in the vicinity of the gate edge and the heavily-diffused source/drain region is arranged outside the lightly-diffused source/drain region. However, the source/drain structure is not limited to a specific structure. In addition, the upper portion of the source/drain structure may be silicided.

In the second embodiment, the first gate insulating film 204A may be, for example, a gate insulating film made of a high dielectric constant material with a relative dielectric constant of 10 or higher. In this case, a silicon oxide film serving as a buffer insulating film may be inserted between the high-dielectric-constant gate insulating film and the substrate 201. With this structure, degradation of the interface between the high-dielectric-constant gate insulating film and the substrate 201 can be prevented. In the case where the first gate insulating film 204A is a high-dielectric-constant gate insulating film, the second gate insulating film 204B may be the same high-dielectric-constant gate insulating film or a gate insulating film made of another material, for example, a SiO₂ film. That is to say, the first and second gate insulating films 204A and 204B may not be composed of the same gate insulating film. Alternatively, another structure may be employed in which a relatively thin SiO₂ film is used as the first gate insulating film 204A and a relatively thick SiO₂ film is used as the second gate insulating film 204B.

In the second embodiment, a silicon layer with oxygen added thereto is used as the silicidation blocking layer 212 of the second gate electrode 205B with a long gate length. Instead of this, a silicon layer with another impurity such as nitrogen added thereto may be used. Alternatively, as the material for the silicidation blocking layer 212, use may be made of metal having a higher melting point than the silicidation temperature of the silicide layer 213 to be formed in the upper portion of the second gate electrode 205B, TiN, metal oxide, or the like. Preferably, the silicidation blocking layer 212 is basically made of a conductive material. However, as the silicidation blocking layer 212, use may be made of an insulating film such as a native oxide film having such an extremely small thickness as not to affect the conductivity of the whole of the second gate electrode 205B.

In the second embodiment, an insulative substrate with a semiconductor region may be used instead of the semiconductor substrate 201.

In the second embodiment, a third gate electrode having a short gate length and not fully silicided may be additionally provided as another electrode different from the fully-silicided first gate electrode 205A with a short gate length.

### Third Embodiment

A method for fabricating a semiconductor device according to a third embodiment of the present invention will be described below with reference to the accompanying drawings. This description will be made using an exemplary case where this method is employed for fabrication of an Nch MISFET having the same structure as the device of the first embodiment.

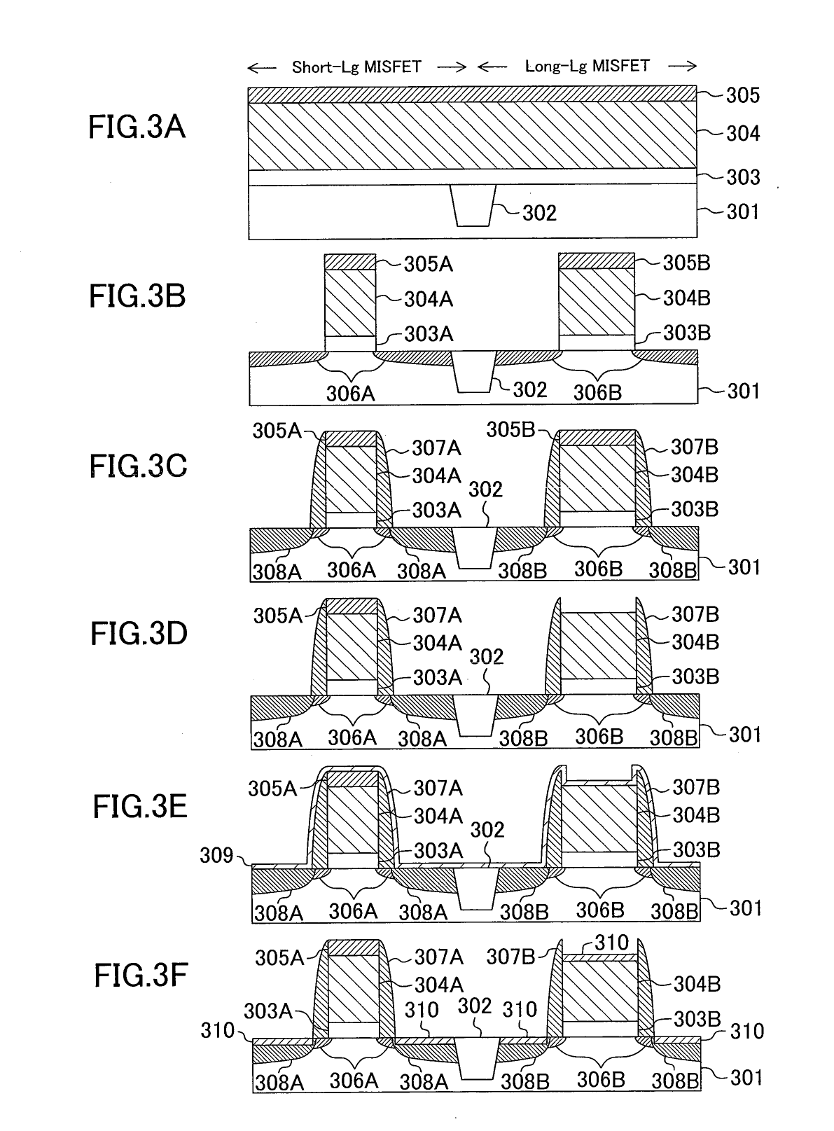

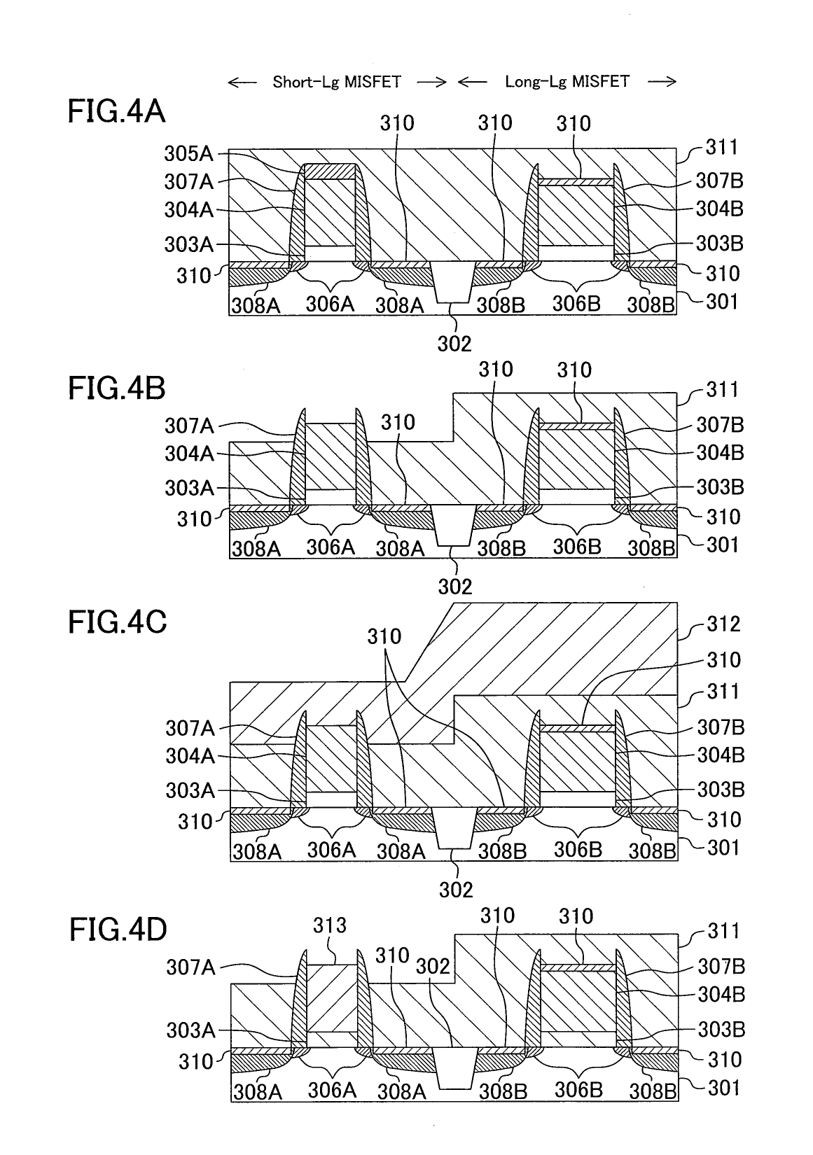

FIGS. 3A to 3F and 4A to 4D are sectional views showing process steps of the method for fabricating a semiconductor device according to the third embodiment.

Referring to FIG. 3A, first, an isolation region 302 made of, for example, an STI is selectively formed in a surface portion of a p-type semiconductor substrate 301, thereby defining a Short-Lg MISFET formation region and a Long-Lg MISFET formation region. Thereafter, ion implantation is performed on the respective MISFET formation regions to form wells, punch-through stoppers, and channels (all of which are not shown), respectively. The condition of this ion implantation is as follows: for well formation, for example, a B (boron) dopant, an implantation energy of 300 keV, and an implantation dose of 1×10¹³ cm⁻²; for punch-through stopper formation, for example, a B dopant, an implantation energy of 150 keV, and an implantation dose of 1×10¹³ cm⁻²; and for channel formation, for example, a B dopant, an implantation energy of 20 keV, and an implantation dose of 5×10¹² cm⁻².

Next, a gate insulating film 303 of, for example, a silicon oxynitride film (a SiON film) with a thickness of 2 nm is formed on the semiconductor substrate 301, and then a gate-electrode material film 304 of polysilicon or the like with a thickness of 100 nm is deposited on the gate insulating film 303. Thereafter, on the gate-electrode material film 304, ion implantation is performed on the condition of, for example, a P (phosphorus) dopant, an implantation energy of 10 keV, and an implantation dose of 5×10¹⁵ cm⁻², and then a cover film 305 of a silicon oxide film or the like with a thickness of 10 nm is deposited on the gate-electrode material film 304.

Subsequently, using as a mask a photoresist pattern covering a gate-electrode formation region, the cover film 305, the gate-electrode material film 304, and the gate insulating film 303 are sequentially etched as shown in FIG. 3B. Thereby, above the Short-Lg MISFET formation region, a first polysilicon gate electrode 304A with a first gate length is formed with a first gate insulating film 303A interposed therebetween, and above the Long-Lg MISFET formation region, a second polysilicon gate electrode 304B with a second gate length greater than the first gate length is formed with a second gate insulating film 303B interposed therebetween. The top surfaces of the first and second polysilicon gate electrodes 304A and 304B are covered with first and second cover films 305A and 305B, respectively.

Using the first and second cover films 305A and 305B as a mask, ion implantation is performed on the respective MISFET formation regions on the condition of, for example, an As (arsenic) dopant, an implantation energy of 2 keV, and an implantation dose of 1×10¹⁵ cm⁻². Thereby, first n-type extension regions 306A are formed in portions of the substrate 301 located outside the first polysilicon gate electrode 304A, respectively, and second n-type extension regions 306B are formed in portions of the substrate 301 located outside the second polysilicon gate electrode 304B, respectively. Then, on the respective MISFET formation regions, ion implantation for forming a p-type pocket region (not shown) is performed. The condition of this ion implantation is as follows: for example, a B dopant, an implantation energy of 10 keV, and an implantation dose of 3×10¹³ cm⁻².

Next, an insulating film of a silicon nitride film (a SiN film) or the like with a thickness of 50 nm is deposited over the entire surface of the semiconductor substrate 301, and then the deposited insulating film is etched back to form, as shown in FIG. 3C, first and second insulating sidewall spacers 307A and 307B on the side surfaces of the first and second polysilicon gate electrodes 304A and 304B, respectively.

Subsequently, using as a mask the first and second cover films 305A and 305B and the first and second insulating sidewall spacers 307A and 307B, ion implantation is performed on the respective MISFET formation regions on the condition of, for example, an As dopant, an implantation energy of 10 keV, and an implantation dose of 3×10¹⁵ cm⁻². Thereafter, implanted impurities are activated by, for example, spike RTA (rapid thermal annealing) at 1050° C. Thereby, first n-type source-drain regions 308A are formed in portions of the substrate 301 located below the outer sides of the first insulating sidewall spacers 307A when viewed from the first polysilicon gate electrode 304A, and second n-type source-drain regions 308B are formed in portions of the substrate 301 located below the outer sides of the second insulating sidewall spacers 307B when viewed from the second polysilicon gate electrode 304B.

As shown in FIG. 3D, using as a mask a photoresist pattern (not shown) covering the Short-Lg MISFET formation region, the second cover film 305B on the second polysilicon gate electrode 304B is selectively removed by wet etching.

Next, as shown in FIG. 3E, a metal film 309 of Ni or the like with a thickness of 10 nm is deposited over the entire surface of the semiconductor substrate 301, and then RTA is performed to form, as shown in FIG. 3F, a Ni silicide layer 310 in the top portions of the second polysilicon gate electrode 304B and the first and second source-drain regions 308A and 308B. Note that after formation of the Ni silicide layer 310, unreacted portions of the metal film 309 are removed.

Subsequently, as shown in FIG. 4A, an interlayer insulating film 311 with a thickness of, for example, 400 nm is deposited over the entire surface of the semiconductor substrate 301, and then by CMP (chemical mechanical polishing), the interlayer insulating film 311 is polished for planarization to such an amount as not to expose the first cover film 305A on the first polysilicon gate electrode 304A.

As shown in FIG. 4B, using as a mask a photoresist pattern (not shown) covering the Long-Lg MISFET formation region, the interlayer insulating film 311 in the Short-Lg MISFET formation region is etched to such an amount as to expose the first cover film 305A on the first polysilicon gate electrode 304A, and then the first cover film 305A is selectively removed by wet etching. During this etching, the interlayer insulating film 311 over the Short-Lg MISFET formation region is also etched and becomes thin.

Next, as shown in FIG. 4C, a metal film 312 of Ni or the like with a thickness of 100 nm is deposited over the entire surface of the semiconductor substrate 301, and then RTA is performed with the interlayer insulating film 311 covering the second polysilicon gate electrode 304B above the Long-Lg MISFET formation region. Thereby, as shown in FIG. 4D, the first polysilicon gate electrode 304A is completely silicided to form the FUSI gate electrode 313 above the Short-Lg MISFET formation region. Note that after formation of the FUSI gate electrode 313, unreacted portions of the metal film 312 are removed.

As described above, with the third embodiment, the same semiconductor device as the first embodiment can be fabricated by a relatively simple fabrication method. That is to say, the gate electrode of the Short-Lg MISFET formation region (the gate electrode with a short gate length) which makes significant contribution to speed enhancement of the device can be fully silicided selectively without fully siliciding the gate electrode of the Long-Lg MISFET formation region (the gate electrode with a long gate length) which makes no contribution to speed enhancement of the device. Thus, even though miniaturization of the device further advances to narrow the margin for full silicidation, a high-performance device incorporating MISFETs with high driving capability can be provided stably in a simple manner.

In the third embodiment, a single-layer structure composed of a silicon nitride film is used as the structures of the insulating sidewall spacers 307A and 307B. Instead of this, for example, a two-layer structure or a three or more-layer structure may be used which is composed of a silicon oxide film and a silicon nitride film in combination.

In the third embodiment, description has been made of the exemplary case where the present invention is applied to formation of the Nch MISFET. However, it goes without saying that instead of this, the present invention may be applied to formation of a Pch MISFET or a CMOS (complementary metal oxide semiconductor) structure.

In the third embodiment, a SiON film is used as the gate insulating films 303A and 303B. Instead of this, for example, a high-dielectric-constant gate insulating film made of HfSiON or the like may be used. In this case, this film may be formed in the manner in which, for example, a silicon oxide film with a thickness of 0.5 nm is formed as a lower-layer gate insulating film (a buffer insulating film) and then, for example, a HfSiON film with a thickness of 6 nm (1.5 nm in terms of the oxide film thickness) is deposited as an upper-layer gate insulating film.

In the third embodiment, in forming the impurity layers such as the source-drain regions in the respective MISFET formation regions, the ion implantation conditions for the layers are set to be identical. However, it goes without saying that the ion implantation conditions for forming the impurity layers may be modified according to the respective MISFET formation regions.

In the third embodiment, a polysilicon film is used as the material for the gate electrode before silicidation. However, it goes without saying that instead of this, another silicon-containing film such as an amorphous silicon film or a SiGe film may be used.

In the third embodiment, in forming the FUSI gate electrode 313 above the Short-Lg MISFET formation region, the interlayer insulating film 311 is used for the purpose of preventing full silicidation of the second polysilicon gate electrode 304B above the Long-Lg MISFET formation region. However, it goes without saying that such an anti-silicidation film is not limited to the interlayer insulating film 311.

### Fourth Embodiment

A method for fabricating a semiconductor device according to a fourth embodiment of the present invention will be described below with reference to the accompanying drawings. This description will be made using an exemplary case where this method is employed for fabrication of an Nch MISFET having the same structure as the device of the second embodiment.

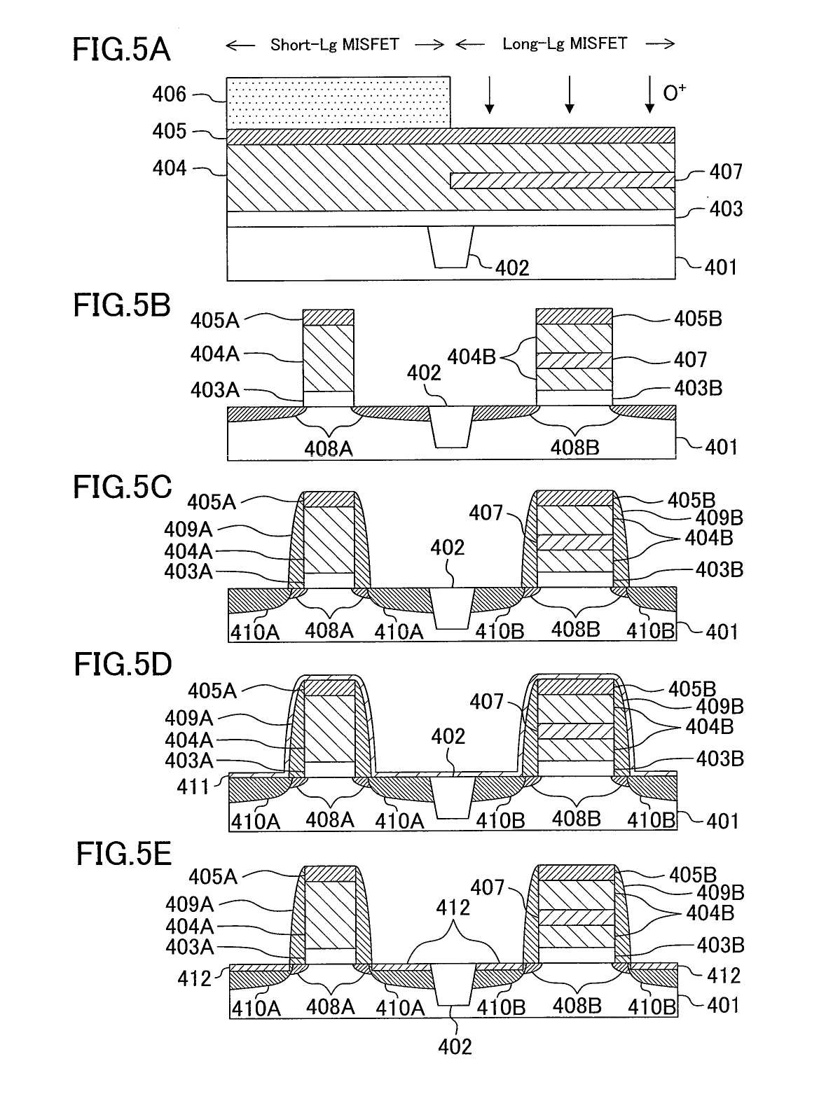

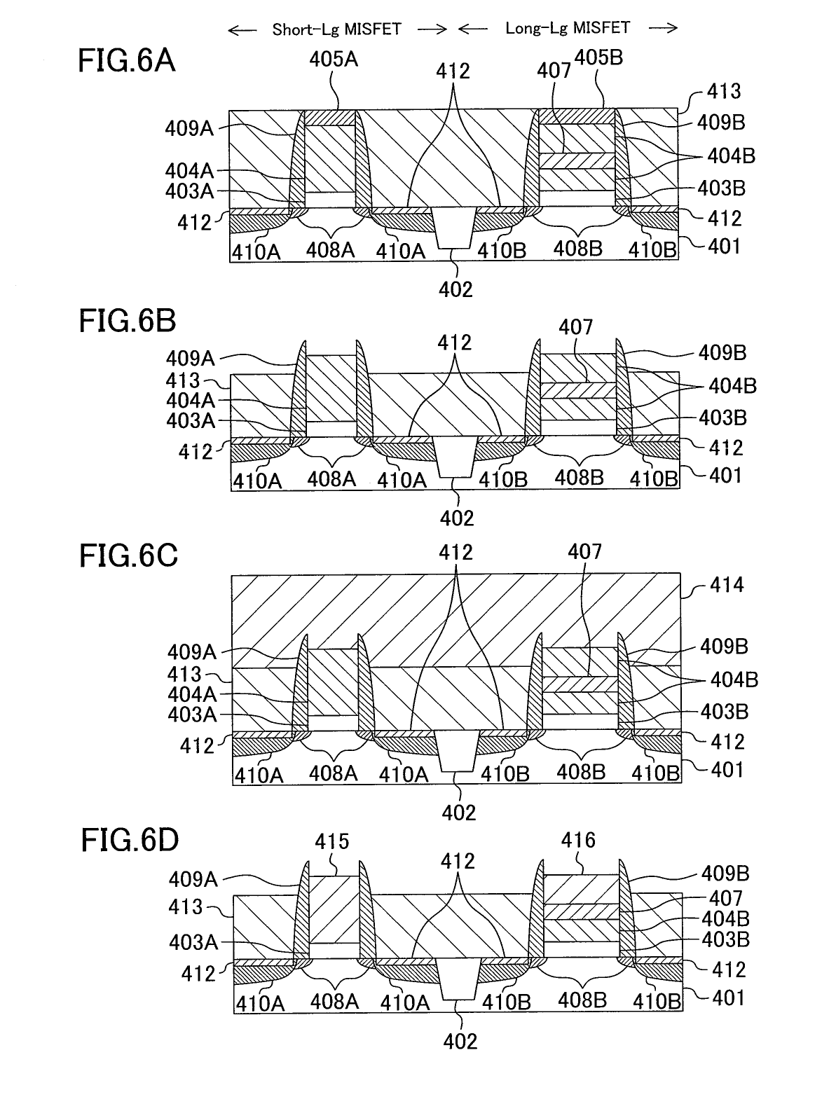

FIGS. 5A to 5E and 6A to 6D are sectional views showing process steps of the method for fabricating a semiconductor device according to the fourth embodiment.

Referring to FIG. 5A, first, an isolation region 402 made of, for example, an STI is selectively formed in a surface portion of a p-type semiconductor substrate 401, thereby defining a Short-Lg MISFET formation region and a Long-Lg MISFET formation region. Thereafter, ion implantation is performed on the respective MISFET formation regions to form wells, punch-through stoppers, and channels (all of which are not shown), respectively. The condition of this ion implantation is as follows: for well formation, for example, a B dopant, an implantation energy of 300 keV, and an implantation dose of 1×10¹³ cm⁻²; for punch-through stopper formation, for example, a B dopant, an implantation energy of 150 keV, and an implantation dose of 1×10¹³ cm⁻²; and for channel formation, for example, a B dopant, an implantation energy of 20 keV, and an implantation dose of 5×102 cm⁻².

Next, a gate insulating film 403 of SiON or the like with a thickness of 2 nm is formed on the semiconductor substrate 401, and then a gate-electrode material film 404 of polysilicon or the like with a thickness of 100 nm is deposited on the gate insulating film 403. Thereafter, on the gate-electrode material film 404, ion implantation is performed on the condition of, for example, a P dopant, an implantation energy of 10 keV, and an implantation dose of 5×10¹⁵ cm⁻², and then a cover film 405 of a silicon oxide film or the like with a thickness of 10 nm is deposited on the gate-electrode material film 404.

Subsequently, using as a mask a photoresist pattern 406 covering the Short-Lg MISFET formation region, ion implantation is performed on the gate-electrode material film 404 on the condition of, for example, an O (oxygen) dopant, an implantation energy of 3 keV, and an implantation dose of 5×10¹⁴ cm⁻². Thereby, a silicidation blocking layer 407 is formed in the gate-electrode material film 404 to lie at a predetermined depth and over the Long-Lg MISFET formation region.

Using as a mask a photoresist pattern covering a gate-electrode formation region, the cover film 405, the gate-electrode material film 404 (including the silicidation blocking layer 407), and the gate insulating film 403 are sequentially etched as shown in FIG. 5B. Thereby, above the Short-Lg MISFET formation region, a first polysilicon gate electrode 404A with a first gate length is formed with a first gate insulating film 403A interposed therebetween, and above the Long-Lg MISFET formation region, a second polysilicon gate electrode 404B (including the silicidation blocking layer 407) with a second gate length greater than the first gate length is formed with a second gate insulating film 403B interposed therebetween. The top surfaces of the first and second polysilicon gate electrodes 404A and 404B are covered with first and second cover films 405A and 405B, respectively.

Next, using the first and second cover films 405A and 405B as a mask, ion implantation is performed on the respective MISFET formation regions on the condition of, for example, an As dopant, an implantation energy of 2 keV, and an implantation dose of 1×10¹⁵ cm⁻². Thereby, first n-type extension regions 408A are formed in portions of the substrate 401 located outside the first polysilicon gate electrode 404A, respectively, and second n-type extension regions 408B are formed in portions of the substrate 401 located outside the second polysilicon gate electrode 404B, respectively. Then, on the respective MISFET formation regions, ion implantation for forming a p-type pocket region (not shown) is performed. The condition of this ion implantation is as follows: for example, a B dopant, an implantation energy of 10 keV, and an implantation dose of 3×10¹³ cm⁻².

Subsequently, an insulating film of SiN or the like with a thickness of 50 nm is deposited over the entire surface of the semiconductor substrate 401, and then the deposited insulating film is etched back to form, as shown FIG. 5C, first and second insulating sidewall spacers 409A and 409B on the side surfaces of the first and second polysilicon gate electrodes 404A and 404B, respectively.

Using as a mask the first and second cover films 405A and 405B and the first and second insulating sidewall spacers 409A and 409B, ion implantation is performed on the respective MISFET formation regions on the condition of, for example, an As dopant, an implantation energy of 10 keV, and an implantation dose of 3×10¹⁵ cm⁻². Thereafter, implanted impurities are activated by, for example, spike RTA at 1050° C. Thereby, first n-type source-drain regions 410A are formed in portions of the substrate 401 located below the outer sides of the first insulating sidewall spacers 409A when viewed from the first polysilicon gate electrode 404A, and second n-type source-drain regions 410B are formed in portions of the substrate 401 located below the outer sides of the second insulating sidewall spacers 409B when viewed from the second polysilicon gate electrode 404B.

Next, as shown in FIG. 5D, a metal film 411 of Ni or the like with a thickness of 10 nm is deposited over the entire surface of the semiconductor substrate 401, and then RTA is performed to form, as shown in FIG. 5E, a Ni silicide layer 412 in the top portions of the first and second source-drain regions 410A and 410B. Note that after formation of the Ni silicide layer 412, unreacted portions of the metal film 411 are removed.

Subsequently, as shown in FIG. 6A, an interlayer insulating film 413 with a thickness of, for example, 400 nm is deposited over the entire surface of the semiconductor substrate 401, and then by CMP, the interlayer insulating film 413 is polished for planarization to such an amount as to expose the surfaces of the cover films 405A and 405B on the polysilicon gate electrodes 404A and 404B, respectively. Thereafter, as shown in FIG. 6B, etch back by wet etching is performed to remove the cover films 405A and 405B. During this etching, the interlayer insulating film 413 is also etched and becomes thin.

Next, as shown in FIG. 6C, a metal film 414 of Ni or the like with a thickness of 100 nm is deposited over the entire surface of the semiconductor substrate 401, and then RTA is performed. Thereby, as shown in FIG. 6D, the first polysilicon gate electrode 404A is completely silicided to form the FUSI gate electrode 415 above the Short-Lg MISFET formation region, and simultaneously a portion of the second polysilicon gate electrode 404B located on the top of the silicidation blocking layer 407 is silicided to form a silicide layer 416. Note that after formation of the FUSI gate electrode 415, unreacted portions of the metal film 414 are removed.

As described above, with the fourth embodiment, the same semiconductor device as the second embodiment can be fabricated by a relatively simple fabrication method. That is to say, the gate electrode of the Short-Lg MISFET formation region (the gate electrode with a short gate length) which makes significant contribution to speed enhancement of the device can be fully silicided selectively without fully siliciding the gate electrode of the Long-Lg MISFET formation region (the gate electrode with a long gate length) which makes no contribution to speed enhancement of the device. Thus, even though miniaturization of the device further advances to narrow the margin for full silicidation, a high-performance device incorporating MISFETs with high driving capability can be provided stably in a simple manner.

Furthermore, with the fourth embodiment, one masking step (the masking step in FIG. 3D for selectively removing the second cover film 305B on the second polysilicon gate electrode 304B) can be eliminated as compared with the third embodiment. This offers the advantage of process simplification.

In the fourth embodiment, oxygen ions are implanted into the gate-electrode material film 404 in order to form the silicidation blocking layer 407. However, the ion to be implanted is not limited to this, and alternatively ion implantation may be performed with another impurity that does not affect activation of the gate-electrode material film 404, such as F, N, Ge, or C.

In the fourth embodiment, after deposition of the cover film 405 on the gate-electrode material film 404, ion implantation for forming the silicidation blocking layer 407 is performed on the gate-electrode material film 404. Instead of this, ion implantation for forming the silicidation blocking layer 407 may be performed after formation of the gate-electrode material film 404 and before formation of the cover film 405.

In the fourth embodiment, a single-layer structure composed of a silicon nitride film is used as the structures of the insulating sidewall spacers 409A and 409B. Instead of this, for example, a two-layer structure or a three or more-layer structure may be used which is composed of a silicon oxide film and a silicon nitride film in combination.

In the fourth embodiment, description has been made of the exemplary case where the present invention is applied to formation of the Nch MISFET. However, it goes without saying that instead of this, the present invention may be applied to formation of a Pch MISFET or a CMOS structure.

In the fourth embodiment, a SiON film is used as the gate insulating films 403A and 403B. Instead of this, for example, a high-dielectric-constant gate insulating film made of HfSiON or the like may be used. In this case, this film may be formed in the manner in which, for example, a silicon oxide film with a thickness of 0.5 nm is formed as a lower-layer gate insulating film (a buffer insulating film) and then, for example, a HfSiON film with a thickness of 6 nm (1.5 nm in terms of the oxide film thickness) is deposited as an upper-layer gate insulating film.

In the fourth embodiment, in forming the impurity layers such as the source-drain regions in the respective MISFET formation regions, the ion implantation conditions for the layers are set to be identical. However, it goes without saying that the ion implantation conditions for forming the impurity layers may be modified according to the respective MISFET formation regions.

In the fourth embodiment, a polysilicon film is used as the material for the gate electrode before silicidation. However, it goes without saying that instead of this, another silicon-containing film such as an amorphous silicon film or a SiGe film may be used.

### Modification of Fourth Embodiment

A method for fabricating a semiconductor device according to one modification of the fourth embodiment of the present invention will be described below with reference to the accompanying drawings.

This modification differs from the fourth embodiment in the following point. In the fourth embodiment, the silicidation blocking layer 407 is formed by ion implantation, while in this modification, the gate-electrode material film 404 is deposited in two steps and the silicidation blocking layer 407 is formed between the deposition in the first step and the deposition in the second step.

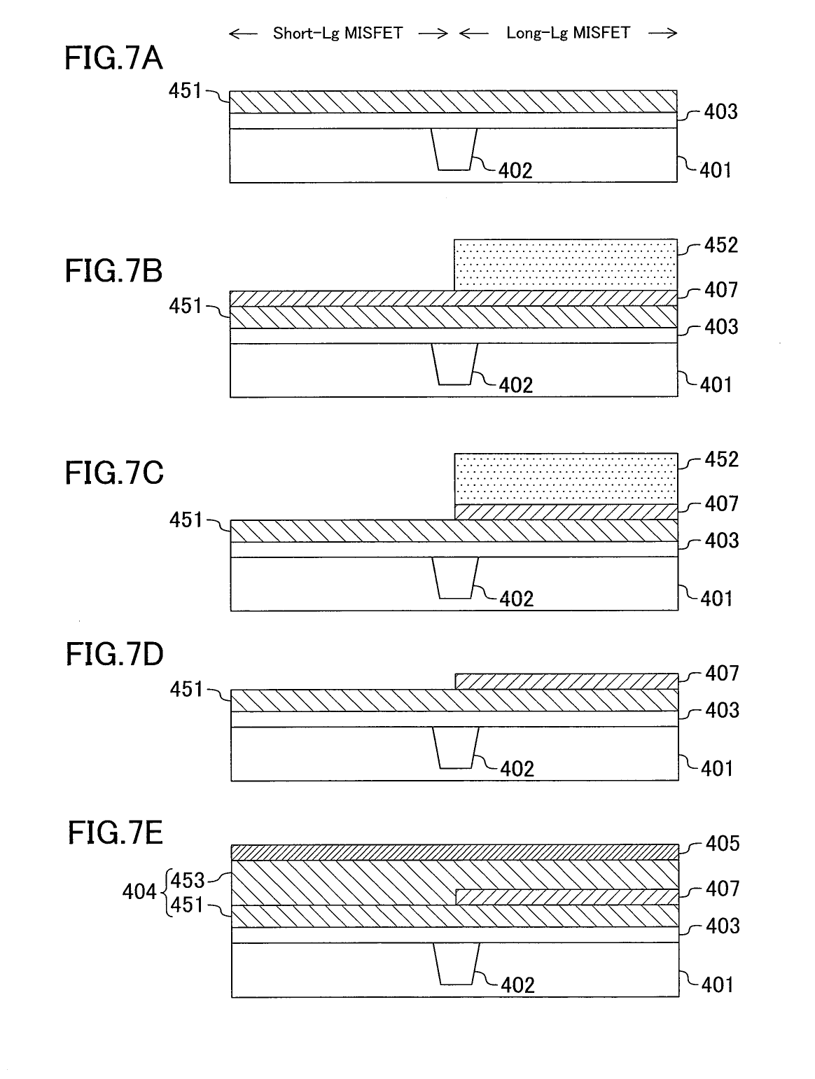

FIGS. 7A to 7E are sectional views showing process steps of the method for fabricating a semiconductor device according to this modification.

Referring to FIG. 7A, first, in the same manner as the fourth embodiment, the process steps up to the formation step of the gate insulating film 403 are carried out, and then a first gate-electrode material film 451 of polysilicon or the like with a thickness of 50 nm is deposited on the gate insulating film 403.

Next, as shown in FIG. 7B, the silicidation blocking layer 407 of TiN or the like with a thickness of 2 nm is formed on the first gate-electrode material film 451, and then a photoresist pattern 452 covering the Long-Lg MISFET formation region is formed.

Subsequently, as shown in FIG. 7C, using the photoresist pattern 452 as a mask, the silicidation blocking layer 407 is etched to selectively remove the portion of the silicidation blocking layer 407 over the Short-Lg MISFET formation region.

As shown in FIG. 7D, the photoresist pattern 452 is removed, and then a second gate-electrode material film 453 of polysilicon or the like with a thickness of 50 nm is deposited over the first gate-electrode material film 451 including the top of the silicidation blocking layer 407 remaining over the Long-Lg MISFET formation region. In this step, the stacked structure composed of the first and second gate-electrode material films 451 and 453 corresponds to the gate-electrode material film 404 in the fourth embodiment shown in FIG. 5A. Thereafter, on the gate-electrode material film 404, ion implantation is performed on the condition of, for example, a P dopant, an implantation energy of 10 keV, and an implantation dose of 5×10¹⁵ cm⁻², and then a cover film 405 of a silicon oxide film or the like with a thickness of 10 nm is deposited on the gate-electrode material film 404.

The process steps subsequently carried out are identical to the steps of the fourth embodiment shown in FIGS. 5B to 5E and 6A to 6D.

With this modification described above, the same effects as the fourth embodiment can be provided.

In this modification, TiN is used as the material for the silicidation blocking layer 407. Instead of this, use may be made of metal or metal oxide having a higher melting point than the silicidation temperature of the silicide layer 416 to be formed in the upper portion of the second polysilicon gate electrode 404B of the Long-Lg MISFET formation region. Preferably, the silicidation blocking layer 407 is basically made of a conductive material. However, as the silicidation blocking layer 407, use may be made of an insulating film such as a native oxide film having such an extremely small thickness as not to affect the conductivity of the whole of the gate electrode.

In this modification, after formation of the gate-electrode material film 404 composed of the first and second gate-electrode material films 451 and 453 and the silicidation blocking layer 407, impurity ions are implanted into the gate-electrode material film 404. Instead of this, impurity ions may also be implanted after deposition of the first gate-electrode material film 451 and before formation of the silicidation blocking layer 407 (the condition of this implantation is, for example, a P dopant, an implantation energy of 5 keV, and an implantation dose of 5×10¹⁵ cm⁻²).

What is claimed is:

1. A semiconductor device comprising:
a first gate electrode formed above a first active region in a substrate with a first gate insulating film interposed therebetween; and
a second gate electrode formed above a second active region in the substrate with a second gate insulating film interposed therebetween,
wherein the first gate electrode has a shorter gate length than the second gate electrode,
the first gate electrode is fully silicided, and
at least a portion of the second gate electrode in contact with the second gate insulating film is not silicided.

2. The device of claim 1,
wherein the gate length of the first gate electrode ranges from the minimum design rule to twice the minimum design rule, inclusive.

3. The device of claim 1,
wherein the second gate electrode has a silicide layer formed at least in its upper portion.

4. The device of claim 3,
wherein the second gate electrode has a silicidation blocking layer formed below the silicide layer.

5. The device of claim 4,
wherein the silicidation blocking layer is made of metal having a higher melting point than the silicidation temperature of the silicide layer, TiN, metal oxide, or silicon having nitrogen or oxygen added thereto.

6. The device of claim 1,
wherein the first gate insulating film is made of a high dielectric constant material.

7. The device of claim 1,
wherein at least a portion of the second gate electrode in contact with the second gate insulating film is made of silicon.

8. A method for fabricating a semiconductor device, comprising:
the step (a) of forming a silicon-containing film over a substrate having a first active region and a second active region;
the step (b) of patterning the silicon-containing film to form a first gate electrode above the first active region and a second gate electrode above the second active region, the first gate electrode having a first gate length, the second gate electrode having a longer second gate length than the first gate length; and
the step (c) of fully siliciding the first gate electrode,
wherein in the step (c), at least a portion of the second gate electrode in contact with the second gate insulating film is not silicided.

9. The method of claim 8,
wherein in the step (c), the first gate electrode is fully silicided with the second gate electrode covered with an anti-silicidation film.

10. The method of claim 8, further comprising, between the steps (b) and (c), the step of siliciding an upper portion of the second gate electrode.

11. The method of claim 8,
wherein in the step (a), a silicidation blocking layer is formed inside a portion of the silicon-containing film located over the second active region, and
in the step (c), the first gate electrode is fully silicided, and simultaneously a portion of the second gate electrode located on the top of the silicidation blocking layer is silicided.

12. The method of claim 11,
wherein in the step (a), after formation of the silicon-containing film, impurities are selectively implanted into a portion of the silicon-containing film located over the second active region, thereby forming the silicidation blocking layer.

13. The method of claim 11,
wherein in the step (a), a first silicon-containing film as a lower-layer portion of the silicon-containing film is formed over the substrate, the silicidation blocking layer is then formed on a portion of the first silicon-containing film located over the second active region, and thereafter a second silicon-containing film as an upper-layer portion of the silicon-containing film is formed on the first silicon-containing film including the top of the silicidation blocking layer.

14. The method of claim 8, further comprising, before the step (a), the step of forming a gate insulating film made of a high dielectric constant material at least on the first active region.
